(19) United States
(12) Patent Application Publication
(10) Pub. No.: US 2014/0048851 A1
(43) Pub. Date: Feb. 20, 2014

(54) SUBSTRATE COMPRISING SI-BASE AND INAS-LAYER

(71) Applicants: Lars-Erik Wernersson, Lund (SE); Sepideh Ghalamestani, Lund (SE)

(72) Inventors: Lars-Erik Wernersson, Lund (SE); Sepideh Ghalamestani, Lund (SE)

(73) Assignee: QUNANO AB, Lund (SE)

(21) Appl. No.: 14/113,438

(22) PCT Filed: Apr. 27, 2012
(86) PCT No.: PCT/SE2012/050447

§ 371 Date: Oct. 23, 2013

(30) Foreign Application Priority Data
Apr. 29, 2011 (SE) 1150381-0

(51) Int. Cl. H01L 21/02; H01L 29/205

(52) U.S. Cl. CPC H01L 21/02617; H01L 21/02381; H01L 21/02538; H01L 29/205
USPC 257/201; 438/478

(57) ABSTRACT

The present invention relates to a substrate (5) comprising a Si-base (1) and an InAs-layer (4) provided on said Si-base where said InAs-layer (4) has a thickness between 100 and 500 nanometers and root-mean-square roughness of the upper surface of said InAs-layer (4) is below 1 nanometer. The invention further relates to a method for forming said substrate. The invention also relates to growing InAs-nanowires (7) as well as a GaSb-layer (17) on said substrate (5).

### FIELD OF INVENTION

The present invention relates in a first aspect to a substrate comprising a stack of a Si-base and an epitaxial InAs-layer.

A second aspect of the present invention relates to method of manufacturing a substrate comprising a stack of a Si-base and an InAs-layer.

### BACKGROUND OF THE INVENTION

InAs is an attractive material for various semiconductor devices due to its high electron mobility and narrow direct band gap. However, integration of InAs on Si has remained a challenge over the last 30 years. A successful integration would enable several photonic devices and electronic circuits on the same chip, making faster n-carrier metal-oxide-semiconductor field-effect transistors (nMOSFETs) and thereby increasing circuit speed and at the same time using a less expensive stacked substrate compared to a bulk InAs substrate, and taking the advantage of the infrastructure and equipment available for large Si-wafers.

Metalorganic vapour phase epitaxy (MOVPE) growth of a relatively thin InAs-layer on Si-base using a two-step method has been mentioned in “Growth of InAs on Si substrates at low temperatures using MOVPE” by Jha et. al. in journal of Crystal Growth 310, pages 4772-4775 (2008). Such an InAs-layer is designated for use as a channel in a transistor why its targeted thickness is around 50 nm. In the disclosed method, a ca. 25 nm thick nucleation layer is deposited on the substrate such that islands of InAs are created, whereupon said layer is annealed, leading inter alia to formation of larger islands, and used in an additional growth step of 50-nm equivalent growth thickness of InAs. Total thickness of the created InAs-layer is therefore appr. 75 nm. However, the disclosed two-step growth method doesn't lead to coalescence of the islands into a flat and even surface. On the contrary, roughness of the surface increases post-annealing. In this context, it has been observed that regularity of the upper surface of the InAs-layer, which is one way to denote quality of the layer, has significant impact on the ability of said layer to support growth of different structures. It is, moreover, desirable to provide the InAs-layer of acceptable quality while at the same time providing the layer of well-defined thickness for specific purposes such as contact layer of a semiconductor component such as a transistor.

One objective of the present invention is therefore to eliminate at least some of the drawbacks associated with the current art.

### SUMMARY OF INVENTION

The above stated objective is achieved by means of a substrate comprising a Si-base and an InAs-layer provided on said Si-base and a method for forming an InAs-layer on a Si-base according to the independent claims, and by the embodiments according to the dependent claims.

More specifically, said InAs-layer has a thickness between 100 and 500 nanometers and root-mean-square roughness of the upper surface of said InAs-layer is below 1 nanometer. As regards thickness of the layer, it is important that the grown InAs-layer is sufficiently thin, i.e. thinner than 500 nanometers. By rendering said layer sufficiently thin the potential problems associated with poor step coverage are avoided. Moreover, since InAs-layer subsequently is used for patterning, a resist is applied onto said InAs-layer. In order to prevent said resist layer from having a non-uniform thickness, it is essential that the InAs-layer is thin enough. On the other hand, the layer needs to be sufficiently thick, i.e. thicker than 100 nanometers, so that undesirable internal resistance is avoided. On the above background, InAs-layer exhibiting desired properties has a thickness between 100 and 500 nanometers. By way of an example, such an InAs-layer is advantageously integrated in a semiconductor component such as transistor to function as the contact layer. As regards quality of the InAs-substrate, i.e. presence of irregularities in the upper surface of said substrate, the root-mean-square roughness of the surface has a value inferior to 1 nanometer. In this context, term root-mean-square roughness is to be construed as an average of peaks and valleys of the profile of the upper surface of the InAs-layer. The InAs-substrate of this quality may subsequently be used in a highly reproducible process for manufacturing of various structures, these structures being grown on said layer.

According to another preferred embodiment of the invention, the InAs-layer contains Sn, which further improves the quality of the InAs layer. Also Sn-doping is preferred to reduce the resistance in the InAs-layer in the case of the InAs-layer being used for instance as source and/or drain.

A preferred embodiment of the present invention comprises a semiconductor arrangement comprising vertical InAs nanowires arranged on the substrate. Preferably, the InAs nanowires are provided in ordered arrays. In a preferred embodiment, a semiconductor device is formed where the vertical InAs nanowires in the said semiconductor arrangement are utilized for wrap around gate MOS-transistors. Wrap around gates provide improved electrostatic control due to the cylindrical geometry which reduces short-channel effects including drain-induced barrier lowering and improve the off-state characteristics. Using the InAs-layer to form source or drain for the MOS-transistors simplifies the processing of the MOS-transistors since no ohmic contact needs be fabricated to the bottom of the nanowire. For RF-applications it is essential to optimize the ratio between the drive current (or rather the transconductance) and the capacitances (intrinsic and parasitic). For this purpose it is essential to place the nanowires in arrays where the close packing helps to minimize the parasitics.

In a preferred embodiment of the invention, a GaSb-layer is grown on the InAs-layer, thereby creating a heterostructure where the conduction band of the InAs-layer has a negative energy offset to the valence band of GaSb-layer. This type II band alignment is used in some device applications such as infrared detectors. In a further preferred embodiment of the present invention comprises a semiconductor structure comprising GaSb nanowires grown on the GaSb-layer, which GaSb nanowires are suitable candidates for high-speed electronic devices. Other heterostructures are also thinkable to be formed using the InAs-layer, for instance to realize other photodetectors or tunnel field effect transistors

In a second aspect of the invention there is provided a method of making a substrate according to the invention comprising an InAs-layer on a Si-base. The method comprises the steps of providing a Si-base, sequentially forming thereafter at least two nucleation layers of InAs on the Si-base, wherein formation of each nucleation layer comprises the steps of growing a layer of InAs and annealing said layer of InAs, growing, subsequently, a layer of InAs on the uppermost nucleation layer and, finally, annealing said layer of InAs. In this context, by a nucleation layer, a layer of Stranski-Krastanow islands is meant. By growing the InAs-layer intermediary at least two nucleation layers, as opposed to growth by means of a single nucleation layer of the prior art, a surprising effect of improving quality of the entire layer is achieved. This is in a non-limitative way exemplified by a significant reduction of the hole density in the upper surface of the layer. A “surface hole” is here a physical hole extending on the order of 0.1 to 10 μm in at least one lateral direction of the InAs-layer throughout the layer whereas “hole density” is a measure of how many holes (as defined above) there are per unit area of a layer. A “surface hole density” includes a condition with zero surface holes per unit area.

In another preferred embodiment of the method of the present invention, the quality of the InAs layer is further improved by introduction of Sn-doping.

In yet another preferred embodiment of the method of the present invention the annealing of the Si-base is performed for example at 600-800° C. for 1 to 10 minutes under AsH₃ flow, to transform the surface of the Si-base from H-terminated to As-terminated and formation of each nucleation layer comprises growing at a temperature of 300° C. to 400° C. for 5 to 15 minutes and annealing at a temperature of 500° C. to 700° C. for 3 to 9 minutes. A further preferred embodiment of the method of the invention comprises growing an InAs-layer on the uppermost nucleation layer at a temperature of 500° C. to 700° C. for 30 to 60 minutes.

A yet further preferred embodiment of the method of the invention comprises a method of forming a semiconductor arrangement comprising InAs nanowires on substrate comprising an InAs-layer on a Si-base. A further of the method according to the invention comprises forming heterostructure comprising a GaSb-layer on the said InAs-layer, thereby creating a structure suitably for example for infrared detectors. A yet further yet embodiment of the method according to the invention comprises forming a semiconductor structure comprising GaSb nanowires on the said GaSb-layer.

### SHORT DESCRIPTION OF FIGURES

FIG. 1:

Schematic structure of a substrate according to the invention comprising a stack of a Si-base and an InAs-layer, which InAs-layer comprises four nucleation InAs-layers and one supplemental InAs-layer positioned on top of the uppermost nucleation layer.

FIG. 2:

Scanning electron microscopy (SEM) image of a top surface of a substrate,
a: with one nucleation layer (comparison),
b: with four nucleation layers.

FIG. 3:

Surface hole density dependence on the number of nucleation layers.

FIG. 4:

Schematic of fabrication of semiconductor device comprising MOS-transistor utilizing a semiconductor arrangement comprising InAs-nanowires grown on a substrate according to the invention:
a: after formation of InAs nanowires,
b: after formation source alternatively the drain,
c: after formation of first spacer layer,
d: after formation of gate material layer,
e: after formation of gate,
f: after formation of second spacer layer,
g: after formation drain layer,
h: after formation of drain alternatively source.

FIG. 5:
a: Schematic of a heterostructure comprising a GaSb layer on a substrate according to the invention.
b: Schematic of a semiconductor structure comprising GaSb nanowires on a GaSb-layer on a substrate according to the invention.

FIG. 6:

SEM-images of InAs nanowires grown on a substrate according to the invention.

FIG. 7
a: SEM-image of lithographically defined InAs nanowires in arrays with different diameter and spacing grown on a substrate according to the invention.
b: SEM-image of a nanowire array grown on a substrate according to the invention.
c: Diameter distribution of a defined pattern with average of 45 nm.
d: High resolution transmission electron microscope (TEM) image of a Sn-doped InAs nanowire grown on a substrate according to the invention.

FIG. 8:

DC characteristics and Post-annealing RF characteristics of a transistor chip comprising MOS-transistors on InAs nanowires arranged on a substrate according to the invention.

FIG. 9:

Switching sequence of material flow used to form an InSb-like interface structure in the forming of a GaSb-layer on a substrate according to the invention.

### DETAILED DESCRIPTION OF EMBODIMENTS OF THE INVENTION

The present invention will now be described more fully hereinafter with reference to the accompanying drawings, in which preferred embodiments are shown. This invention may, however, be embodied in many different forms and should not be construed as limited to the embodiments set forth herein; rather, these embodiments are provided so that this disclosure will be thorough and complete, and will fully convey the scope of the invention to those skilled in the art. In the drawings, like reference signs refer to like elements.

In the present application the following terms and expressions shall be taken to have the following meanings:

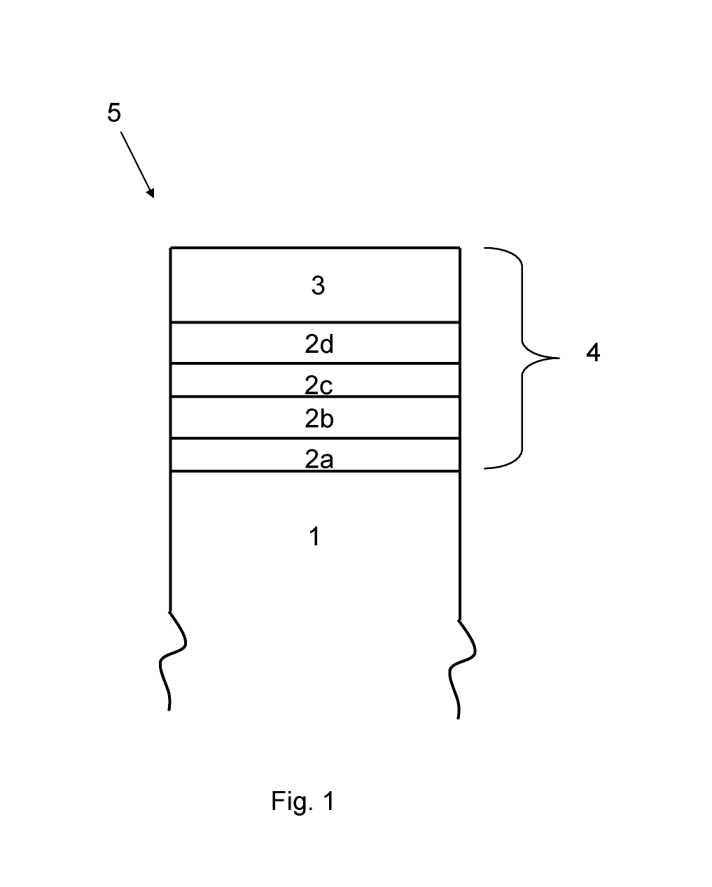

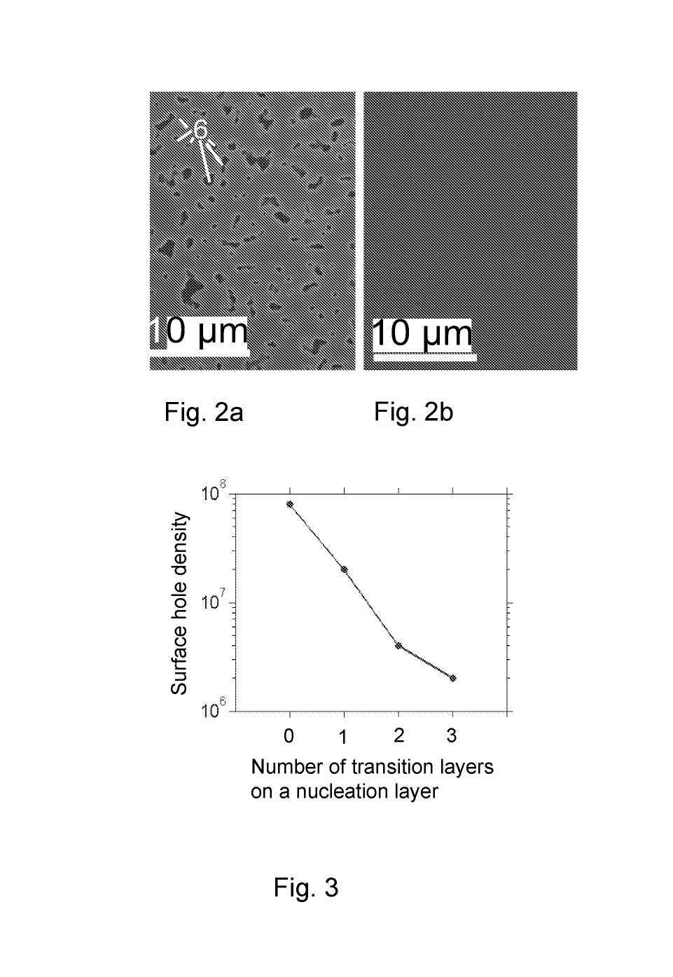

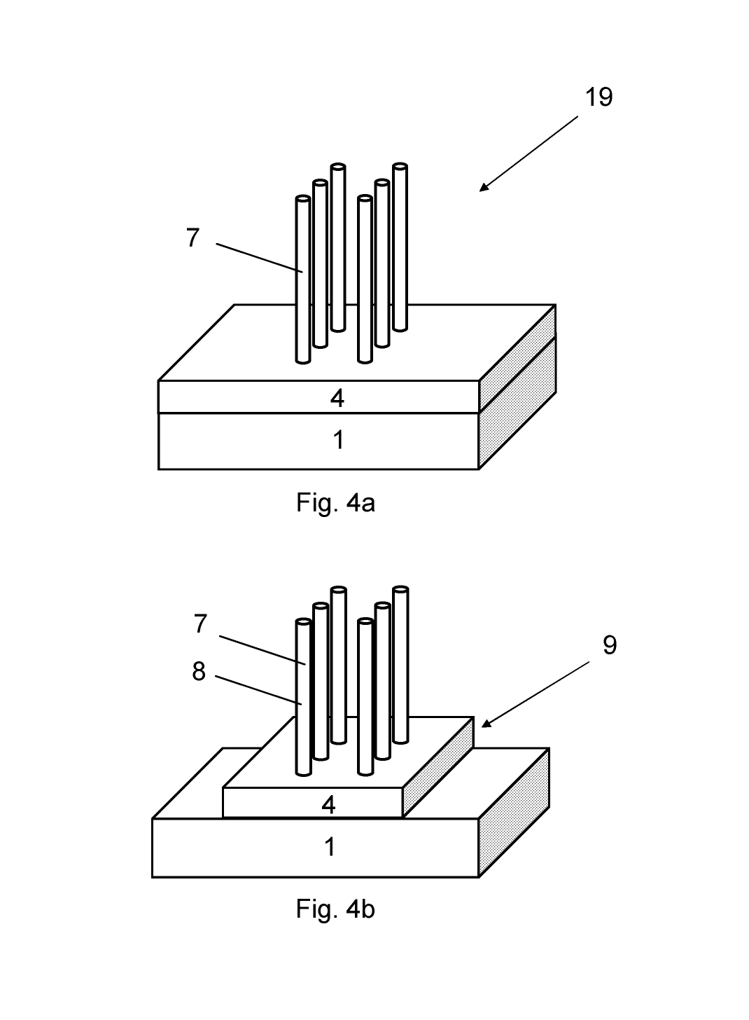

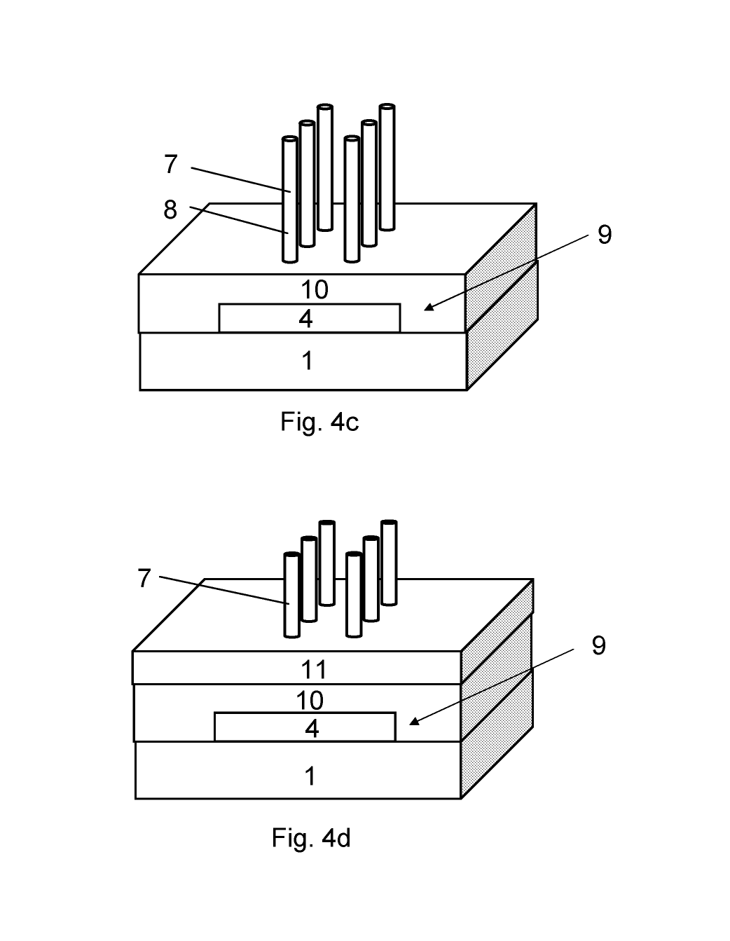

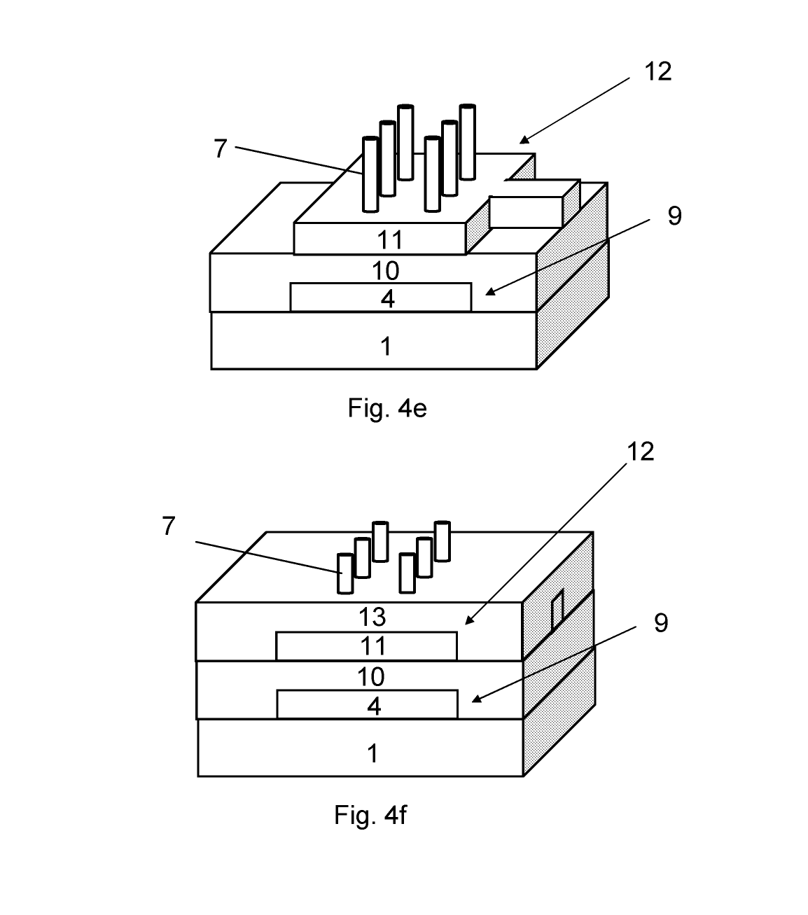

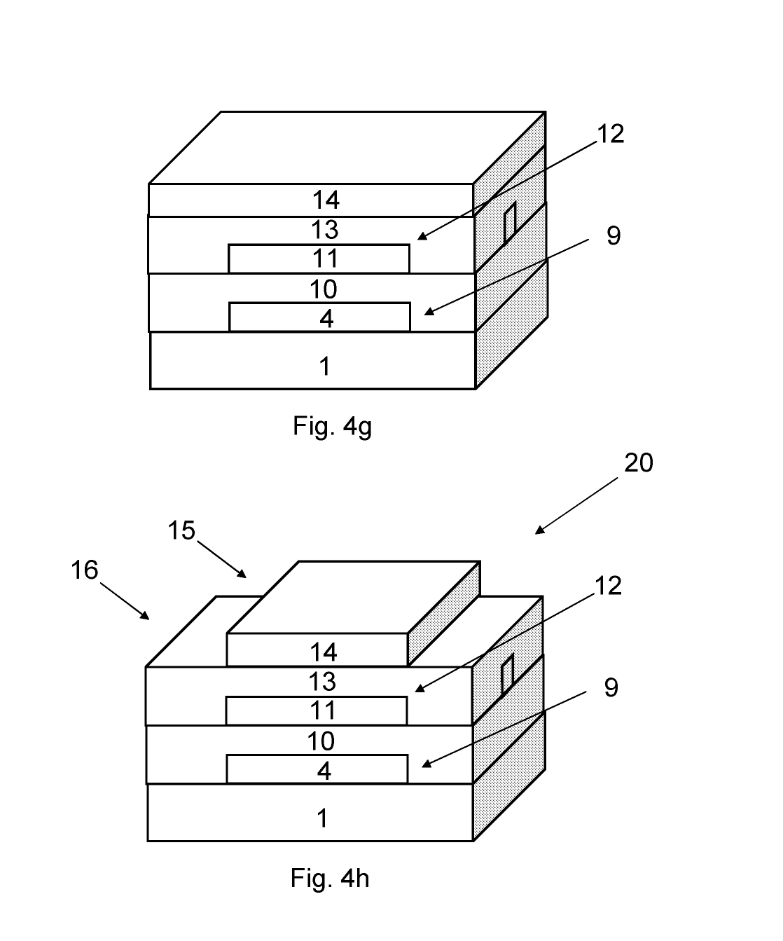

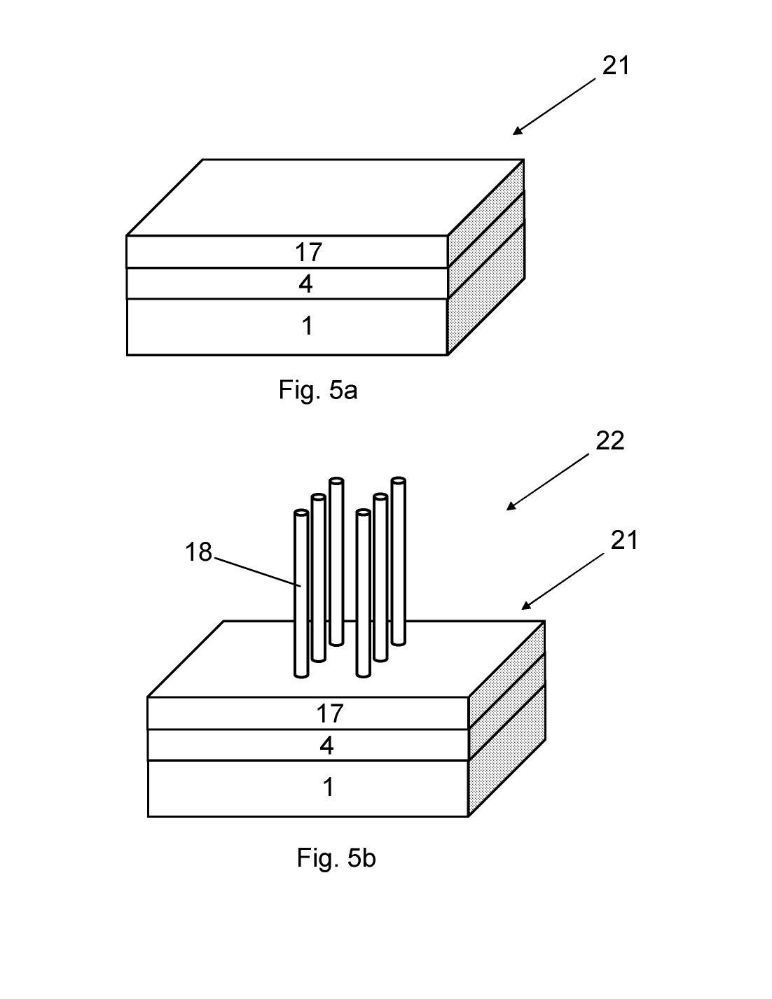

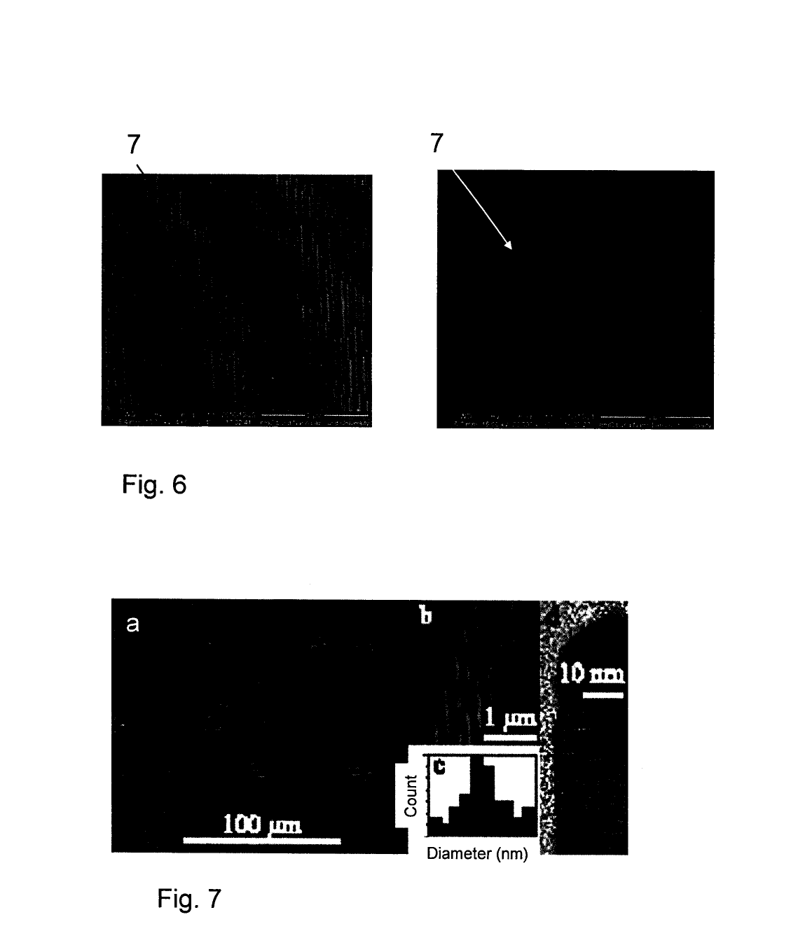

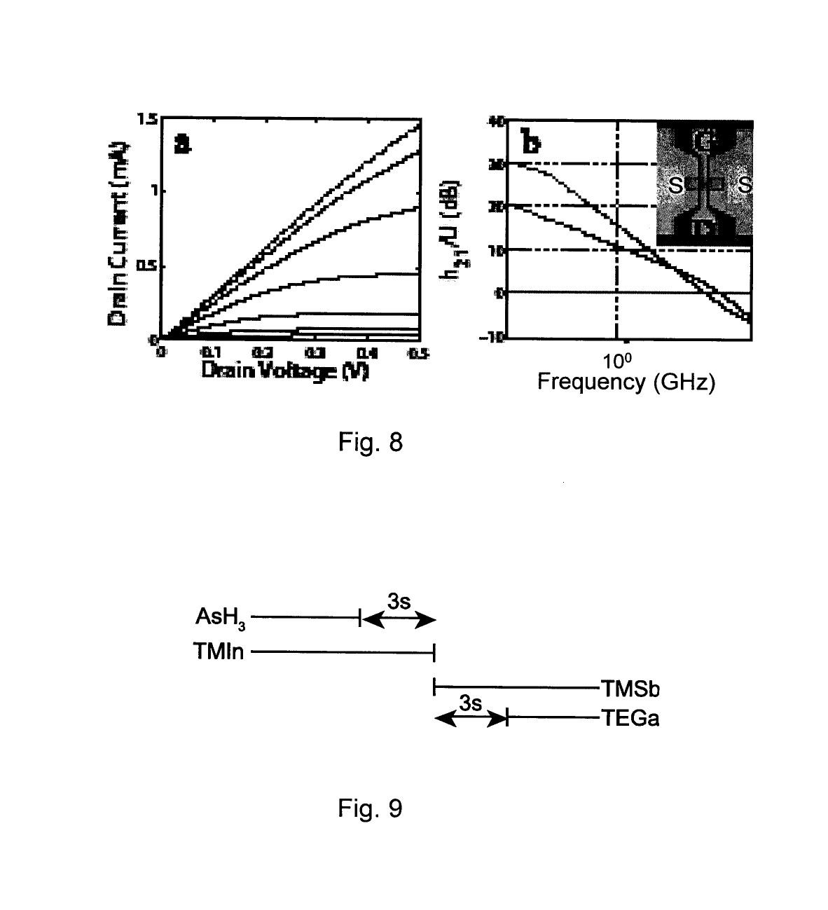

FIG. 1 shows schematically an embodiment of the invention which comprises a substrate 5. The substrate 5 comprises a Si-base 1 and an InAs-layer 4. The InAs layer 4 comprises four nucleation layers 2a 2b, 2c, 2d and one supplemental InAs-layer 3 positioned on top of the uppermost nucleation layer. With a nucleation layer is meant a layer of Stranski-Krastanow islands. Analysis of the InAs-surface by means of an Atomic Force Microscope (AFM) revealed that surface root-mean-square roughness (RMS) of a sample with one nucleation layer in at least one part of the surface is 1.5 nm. Corresponding RMS-value decreases to 0.7 nm for the sample with 2 nucleation layers. For three and more nucleation layers, the RMS-value is reduced to 0.4 nm. Moreover, further analysis by means of a Sweep Electron Microscope (SEM) shows that formation of an InAs-layer 4 consisting of only the nucleation layer 2a on a Si-base 1 results in a surface hole density of 8×10⁷ cm⁻² remaining on the substrate 5. In this context, FIG. 2a shows a top-down SEM-image with surface holes 6, some of which are marked, on such a substrate. For an InAs-layer consisting of four nucleation layers 2a, 2b, 2c, 2d, which is an example of a substrate 5 according to the invention, the density of surface holes 6 is suppressed to a level of 2×10⁶ cm⁻². FIG. 2b shows a top-down SEM-image of such a substrate where no surface holes are seen in the image. FIG. 3 shows how the density of surface holes 6 decreases on the substrate 5 when increasing in the InAs-layer 4 the number of nucleation layers from one to four nucleation layers 2b, 2c, 2d. For an InAs-layer consisting of two nucleation layers 2a and 2b which is another example of a substrate 5 according to the invention, the density of surface holes 6 is suppressed to a level of 2×10⁷ cm⁻². For an InAs-layer consisting of three nucleation layers 2a, 2b, 2c, which is another example of a substrate 5 according to the invention, the density of surface holes 6 is suppressed to a level of 4×10⁶ cm⁻². InAs nanowires 7 are preferably formed on the substrate 5 according to the invention with an InAs-layer 4 on a Si-base 1 thereby forming the semiconductor arrangement 19 schematically shown in FIG. 4a.

The InAs nanowires 7 are suitable to be used to build MOS transistors. In FIG. 4b the structure is schematically shown after formation of a conformal gate oxide 8 and formation of the source 9 or alternatively a drain by patterning the InAs-layer 4. Then, a first spacer layer 10 is formed preferably by spin-coating and back etching as schematically shown in FIG. 4c. Then a gate material layer 11 is formed preferably by deposition and etch back as schematically shown in FIG. 4d. Then a gate 12 is formed by pattering the gate layer 11, as shown schematically in FIG. 4e. Then a second spacer layer 13 is formed by preferably spin-coating and back etching as shown schematically in FIG. 4f. Then a drain layer 14 is formed which connects the InAs nanowires 7 above the second spacer layer 12 as shown schematically in FIG. 4g. Drain 15 or alternatively the source is then formed by patterning the drain layer 14 and thereby a MOS transistor 16 comprising a plurality of InAs nanowires is formed in a semiconductor device 20 as schematically shown in FIG. 4h. The MOS transistor 16 can of course also be formed with only one InAs nanowire.

The substrate 5 according to the invention is also suitable to use for formation of a heterostructure of for instance GaSb on InAs. FIG. 5a schematically shows a GaSb-layer 17 formed on the InAs-layer 4 formed on the Si-base 1, thereby forming a heterostructure 21. It is suitable to grow GaSb nanowires 18 on the GaSb-layer 17 as schematically shown as a semiconductor structure 22 in FIG. 5b.

### Processing Examples

### Formation of the InAs-layer on Si-base

Highly resistive Si (111) is preferably used as a Si-base 1. Prior to the growth, the Si-base 1 is preferably cleaned by a standard RCA cleaning method. The RCA cleaning procedure is known to remove possible contaminants on the surface, including carbon, and it subsequently forms a very thin oxide layer on the surface. The last cleaning step is etching of this oxide by dipping the substrates in HF solution (10%). This produces a H-terminated surface and protects the surface against oxidation during the loading time inside the reactor.

After being loaded inside the reactor, for instance a horizontal MOVPE reactor, the Si-base 1 is preferably annealed, for example for 5 min at 700° C. under AsH₃ flow, to transform the surface of the Si-base 1 from H-terminated to As-terminated. Then a nucleation layer 2a of Stranski-Krastanov islands is grown. The growth of the nucleation layer 2a is preferably performed at a low temperature, for example for 350° C. for 10 min using Trimethylindium (TMIn), Trimethylgallium (TMGa), Triethylgallium (TEGa), Arsine (AsH₃), and Trimethylantimony (TMSb) as precursors with hydrogen as a carrier gas with a total flow of 13 1/min and a reactor pressure of 100 mbar. Preferably the nucleation layer 2a is doped with Sn using Triethylzinc (TESn). The growth is preferably followed by a ramping up the temperature to for example 600° C., where the nucleation layer 2a is annealed for example for 6 min. According to the invention, formation of at least one additional nucleation layer is performed. In this processing example, growth and anneal with the same process parameters above as for the nucleation layer, were used for the formation of the at least one additional nucleation layer. The example in FIG. 1 shows schematically that growth and anneal has been done 3 times, resulting in additional nucleation layers 2b, 2c, and 2d on the nucleation layer 2a. Optionally, after the formation of the at least one additional nucleation layer, a supplemental layer 3, which is schematically shown in FIG. 1, is formed by growth at the same high temperature as used in anneal of the at least one additional nucleation layer. The TMIn molar fraction is preferably constant during the deposition at 1.88×10⁻⁵. The AsH₃ molar fraction is preferably 3.46×10⁻³ during the growth of the nucleation layers and is preferably decreased one order of magnitude for the growth of the supplemental layer. Doping is preferably performed by introducing TESn with molar fraction of for example 2.33×10⁻⁷ during the supplemental layer growth.

Formation of nanowires on said InAs-layer The formation of InAs nanowires 7 on the InAs-layer 4 is for instance done by e-beam patterning of Au discs in a lift-off process and subsequent growth of the InAs nanowires 7. Arrays (dimensions of 0.8×0.3 mm) consisting of diameters from 25 to 55 nm and spacings of 200, 300, and 500 nm were defined at 5 different positions at various positions at the surface. InAs nanowire growth is preferably done at 420° C. with TMIn and AsH₃ as precursors and respective molar fractions of 4.18×10⁻⁶ and 3.85×10⁻⁴. The InAs nanowires 7 are preferably doped with TESn molar fraction of 6.41×10⁻⁷ roughly corresponding to a doping concentration of 2×10¹⁵ cm⁻³. Inspection by means of SEM revealed successful InAs nanowire growth at all the defined patterns with 100% yield, as seen FIG. 6. The successful growth of vertical InAs nanowires 7 verifies the formation of a (111) B-oriented surface of the underlying InAs-layer.

Furthermore, it confirms suppression of anti-phase domains (APD) and presence of a high quality InAs-layer 4. FIG. 7a shows a SEM-image of one part of a defined pattern with various spacings and diameters ranging from 25 to 55 nm, with an image of InAs nanowires with 40 nm diameter and 500 nm spacing, see FIG. 7b. The SEM-results confirm that the InAs nanowires 7 are well positioned and they do not show any tapering. High resolution Transmission Electron Microscopy (HRTEM) was performed on InAs nanowires broken off from the substrate onto carbon film-coated Cu grids in a JEOL-3000F field emission electron microscope operated at 300 kV, demonstrating predominantly wurtzite structure with moderately dense stacking faults and zinc blende inclusions, typical for Sn-doped InAs nanowires, see FIG. 7d.

Statistical analysis on the grown InAs nanowires indicates a maximum diameter variation around the nominal diameters of about 6 nm, as demonstrated for the 45 nm diameter in FIG. 7c. Also, diameter comparison among all the five patterns with the same exposed dose reveals a diameter shift of −15 nm from the first defined pattern to the last one. This diameter shift is due to the beam current shift and focus shift over 10 hours of exposure. In addition, it should be noted that those InAs nanowires located at the end of each row are somewhat longer than the others as they have a larger surrounding collection area.

Formation of MOS-transistors utilizing said InAs-nanowires The conformal gate oxide 8 (for instance HfO₂) is formed on the InAs nanowires for instance at 250° C. by atomic layer deposition. The source 9 or alternatively a drain is formed by patterning the InAs-layer 4 for instance by UV lithography followed by Buffered Oxide Etch (BOE) and H₃PO₄:H₂O₂:H₂O wet etching. The first spacer layer 10, for instance organic, is preferably formed by for instance spin-coating and back etching. The gate material layer 11, for instance a metal such as Tungsten, is deposited for instance by sputtering and etched back using for example SF₆-Ar atmosphere Reactive Ion Etching (RIE) to a gate length of for example ˜250 nm. The gate 12 is formed by patterning of the gate material layer 11 preferably using lithography and etching. The formation of a second spacer layer 13, for instance organic, is for instance done by spin-coating and back etching. The drain layer 14 is formed preferably of InAs with Sn-doping. The drain 15 or alternatively the source is formed by patterning of the drain layer 14 of InAs for instance by UV lithography followed by Buffered Oxide Etch (BOE) and H₃PO₄:H₂O₂:H₂O wet etching. The output characteristic of a transistor consisting of about 180 nanowires with 40 nm diameter is shown in FIG. 8a. The measured drain current at V_{d}=1 V and V_{g}=1 V is 0.11 A/mm normalized to the total circumference of the InAs nanowires. Post-annealing (250° C., 30 min) RF characterization is performed with an Agilent E8361A network analyzer on devices with a drain current level to 0.50 A/mm. The measured S-parameters (calibrated off chip and de-embedded on chip) were utilized to calculate the current gain (h₂₁) and the unilateral power gain (U). FIG. 8b shows the RF characteristics of a transistor where the highest unity current gain cutoff frequency (fₜ) and maximum oscillation frequency (fₘₐₓ) observed were fₜ=9.8 GHz and fₘₐₓ=14.3 GHz for V_{g}=−1.5 V and Vd =0.75 V. A completed chip is illustrated in the inset of 8b where G, S and D represent gate, source, and drain, respectively.

Formation of GaSb-Layer on said InAs-Layer

Depending on the switching sequence of the precursors, different interface structures can be preferentially formed, such as GaAs- and InSb-like. For example a switching sequence in the following order shown in FIG. 9: As off, 3 s pause, In off and simultaneously Sb on, 3 s pause, Ga on, results in a growth of GaSb with InSb interface type.

Formation of GaSb Nanowires on said GaSb-Layer

GaSb nanowires 18 can be grown on the on the GaSb-layer 17 using Au particles on the surface as catalyst. Increasing the TMGa and TMSb molar fractions and lowering the temperature helps the GaSb nanowire nucleation, attributed to reduced surface diffusion of the precursors.

In an experiment no nanowire growth was observed for temperatures above 470° C. Inspections performed by SEM indicate that 420° C. is the optimized temperature for nucleation and that an increased material flow assists the nucleation of more GaSb nanowires. However, a higher material flow facilitates radial growth of the GaSb nanowires and results in increased GaSb nanowire diameter compared to the Au particle.

In the drawings and specification, there have been disclosed typical preferred embodiments of the invention and, although specific terms are employed, they are used in a generic and descriptive sense only and not for purposes of limitation, the scope of the invention being set forth in the following claims.

1. Substrate comprising a Si-base and an InAs-layer provided on said Si-base, wherein said InAs-layer has a thickness between 100 and 500 nanometers and root-mean-square roughness of the upper surface of said InAs-layer is below 1 nanometer.

2. Substrate according to claim 1, wherein the surface hole density in the InAs-layer is equal or less than 2×10⁷ cm⁻².

3. Substrate according to claim 1, wherein the InAs-layer contains Sn.

4. A semiconductor arrangement, wherein the semiconductor arrangement comprises InAs nanowires in ordered arrays, arranged on a substrate according to claim 1.

5. A semiconductor device, wherein the semiconductor device comprises InAs nanowire gate wrap-around MOS-transistors formed by utilizing the InAs nanowires in the semiconductor arrangement according to claim 4.

6. A heterostructure, wherein the heterostructure comprises a GaSb-layer arranged on a substrate according to claim 1.

7. A semiconductor structure, wherein semiconductor structure comprises GaSb nanowires arranged on a heterostructure according to claim 6.

8. A method for forming a InAs-layer on a Si-base, the method comprising:
providing a Si-base,
forming at least two nucleation layers of InAs on the Si-base, formation of each nucleation layer comprising:
growing a layer of InAs, and
annealing said layer of InAs,
growing a layer of InAs on an uppermost nucleation layer, and
annealing said layer of InAs.

9. A method according to claim 8, wherein four nucleation layers of InAs are formed.

10. A method according to claim 8, wherein said growing of a layer of InAs during formation of the nucleation layer takes place at a temperature between 300 and 400° C.

11. A method according to claim 8, wherein said layer of Si is grown between 5 and 15 minutes.

12. A method according to claim 8, wherein said annealing of a layer of InAs during formation of the nucleation layer takes place at a temperature between 500 and 700° C.

13. A method according to claim 12, wherein said layer of InAs is annealed between 3 and 9 minutes.

14. A method according to claim 8 wherein said growing of a layer of InAs on the uppermost nucleation layer takes place at a temperature between 500 and 700° C.

15. A method according to claim 14, wherein said layer of InAs is grown between 30 and 60 minutes.

16. A method according to claim 8, further comprising annealing of the Si-base under arsine (AsH₃) flow to transform a surface of the Si-base from H-terminated to As-terminated.

17. A method according to claim 16, wherein arsine (AsH₃) is used as a precursor during formation of the nucleation layers.

18. A method according to claim 8, wherein Sn is introduced during formation of at least one nucleation layer.

19. A method according to claim 8, wherein Sn is introduced during growth of the layer of InAs on the uppermost nucleation layer.

20. A method according to claim 8, wherein said Si-base is annealed prior to said forming of at least two nucleation layers (2a, 2b) of InAs.

21. A method according to claim 20, wherein said annealing of the Si-base takes place at a temperature between 600 and 800° C.

22. A method according to claim 21, wherein said Si-base is annealed between 1 and 10 minutes.

23. A method of forming a semiconductor arrangement, wherein the method comprises the steps of:
providing a substrate according to claim 1, and
growing InAs-nanowires on the substrate.

24. A method of forming a heterostructure, wherein the method comprises the steps of:
providing a substrate according to claim 1, and
growing a GaSb-layer on the substrate.

25. A method of forming a semiconductor structure, wherein the method comprises the steps of:
providing a heterostructure according to claim 6, and
growing GaSb nanowires on the heterostructure.
